(19) United States
(12) Patent Application Publication
(10) Pub. No.: US 2026/0231368 A1
(43) Pub. Date: Aug. 6, 2026

(54) PRESSING MECHANISM, PROCESSING DEVICE, AND PROCESSING MACHINE

(71) Applicant: Hon. Precision, Inc, Taichung (TW)

(72) Inventors: Ching-Hsiang Yu, Taichung (TW); Chan-Sheng Chang, Taichung (TW)

(73) Assignee: Hon. Precision, Inc, Taichung (TW)

(21) Appl. No.: 19/043,804

(22) Filed: Feb. 3, 2025

(51) Int. Cl. H05K 7/20; G01R 31/28

(52) U.S. Cl. CPC H05K 7/20327; G01R 31/2891

(57) ABSTRACT

A pressing mechanism includes a pressing member, a providing unit, a micro channel unit, and an outlet unit. The pressing member has a pressing face to press the electronic component and the temperature of the electronic component. The providing unit has a main channel, a branch channel, and plural inlet channel communicating with each other at the pressing member. The fluid at the predetermined temperature enters the inlet channels. The micro channel unit has plural micro channels at the pressing member to make the fluid in the inlet channels flow into so as to exchange heat in a large area with the pressing member for controlling the temperature of the electronic component. The outlet unit has a main outlet channel, a converging channel, and plural outlet channels at the pressing member. The heat-exchanged fluid from the micro channels flows into the outlet unit to get out.

### FIELD OF THE INVENTION

The present disclosure relates to a pressing mechanism which is able to exchange heat in a larger area so as to improve the efficiency of temperature control.

### BACKGROUND OF THE INVENTION

Nowadays, an electronic component is processed at a controlled temperature by a processing device having a pressing mechanism, a testing mechanism, a pre-heating mechanism, and a carrying mechanism. For example, in a process at a low temperature, the testing mechanism uses a testing member to support and to test the electronic component. The pressing mechanism is arranged above the testing member, and the pressing mechanism has a pressing member having a pressing face to press and contact the electronic component. The pressing member further has a single channel therein. The channel has an inlet at an end for injection of refrigerant. The refrigerant flows towards the outlet at the other end of the channel. Thus, the pressing member can press the electronic component and control the temperature of the electronic component in order to simulate an environment of using the electronic component at a low temperature.

However, the refrigerant exchanges heat with the electronic component via the pressing face when flowing in the channel, so the temperature of the refrigerant increases. As a result, when the refrigerant flows through the outlet of the channel, the temperature of the refrigerant is higher than the predetermined temperature. That is, the temperatures of two sides of the pressing face are different so that the temperature of the electronic component cannot be controlled well.

The present invention is, therefore, arisen to obviate or at least mitigate the above mentioned disadvantages.

### SUMMARY OF THE INVENTION

One of the objects of the present invention is to provide a pressing mechanism including a pressing member, a providing unit, a micro channel unit, and an output unit. The pressing member has at least one pressing face. The providing unit has at least one main inlet channel, at least one branch channel, and at least one inlet branch channel at the pressing member. The main inlet channel is adapted for injecting a fluid at a predetermined temperature into the branch channel. The branch channel is adapted for injecting the fluid at the predetermined temperature into the inlet branch channel. The micro channel unit has a plurality of micro channels at the pressing member near the pressing face. The micro channels are adapted for injecting the fluid at the predetermined temperature into the inlet branch channel and for exchanging heat with the pressing face to keep a temperature of the pressing face constant. The outlet unit has at least one main outlet channel, at least one converging channel, and at least one outlet branch channel at the pressing member. The outlet branch channel is adapted for injecting an heat-exchanged fluid into the micro channels and for converging the heat-exchanged fluid into the converging channel. The converging channel is adapted for injecting the heat-exchanged fluid into the main outlet channel to output the heat-exchanged fluid. Thereby, the pressing member can quickly keep the temperature of the pressing face constant, and the loss of heat in the channel can be decreased.

One of the objects of the present invention is to provide a pressing mechanism whose providing unit has a plurality of rows of inlet branch channel. The micro channel unit has a plurality of rows of micro channels. The fluid in the main inlet channel enters the branch channel, and the fluid in the branch channel evenly enters the rows of the inlet branch channel, and the fluid at the predetermined temperature in the rows of the inlet branch channel enters the rows of the micro channels at the same time in order to increase the area of heat-exchanging of the pressing face.

One of the objects of the present invention is to provide a pressing mechanism whose micro channel of the micro channel unit is composed of a plurality of plates and has at least one layer of the micro section. Optionally, the micro channel has a plurality of layers of the micro section. Thus, the flow of the fluid can be increased without increasing the length of the micro channel.

One of the objects of the present invention is to provide a processing device including at least one pressing mechanism and at least one support structure. The at least one pressing mechanism includes a pressing member, a providing unit, a micro channel unit, and an output unit in order to press the electronic component and to control the temperature of the electronic component. The at least one support structure has at least one support member for supporting the at least one pressing mechanism.

One of the objects of the present invention is to provide a processing machine including a machine, a providing device, a collecting device, a processing device, and a central control device. The providing device is arranged at the machine and has at least one providing member for receiving at least one electronic component to test. The collecting device is arranged at the machine and has at least one collecting member for receiving at least one tested electronic component. The at least one the processing device is arranged at the machine and includes at least one pressing mechanism and at least one support structure, and further includes at least one testing mechanism and at least one carrying mechanism. The at least one testing mechanism has at least one testing member for testing the electronic component. The at least one carrying mechanism has at least one carrying member for carrying and moving the electronic component. The central control device is for controlling and integrating the devices and the mechanisms to achieve automatic process.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

The present disclosure can be more fully understood by reading the following detailed description of the embodiment, with reference made to the accompanying drawings as follows:

FIG. 1 is a top view showing a first embodiment of a pressing mechanism of the present invention;

FIG. 2 is a front view of a pressing mechanism of the present invention;

FIG. 3 is a partial profile of FIG. 2;

FIG. 4 is a lateral profile of a providing unit and a micro channel unit of the present invention;

FIG. 5 is a lateral profile of an output unit and a micro channel unit of the present invention;

FIG. 6 to FIG. 9 are illustrations of operation of a pressing mechanism of the present invention;

FIG. 10 is a top view showing a second embodiment of a pressing mechanism of the present invention;

FIG. 11 is a profile of a providing unit and a micro channel unit of the present invention;

FIG. 12 is a profile of an output unit and a micro channel unit of the present invention;

FIG. 13 is an illustration of a processing machine of the present invention.

### DETAILED DESCRIPTION OF THE PREFERRED EMBODIMENTS

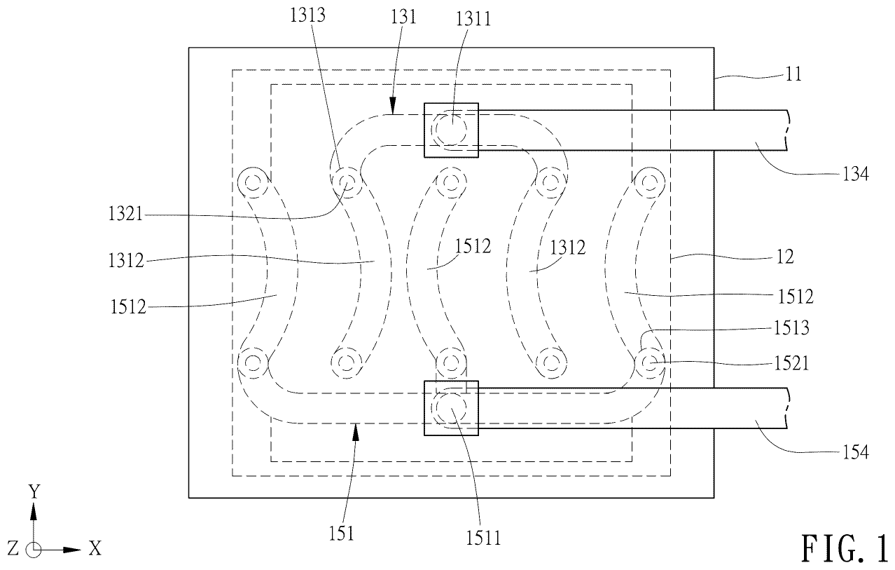

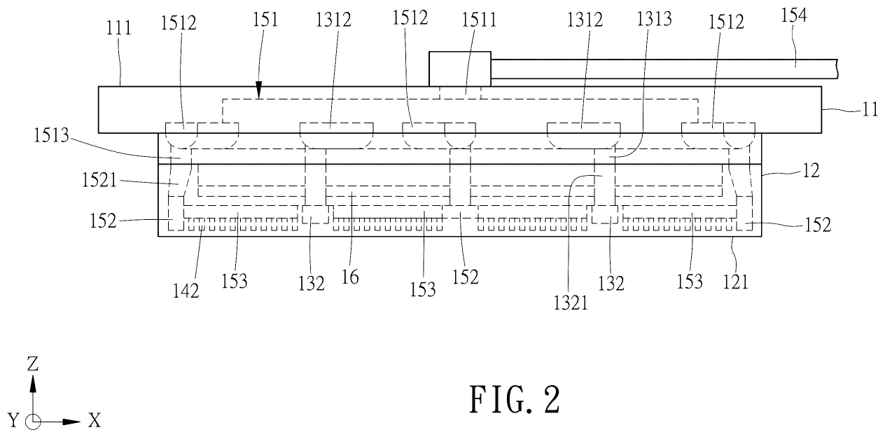

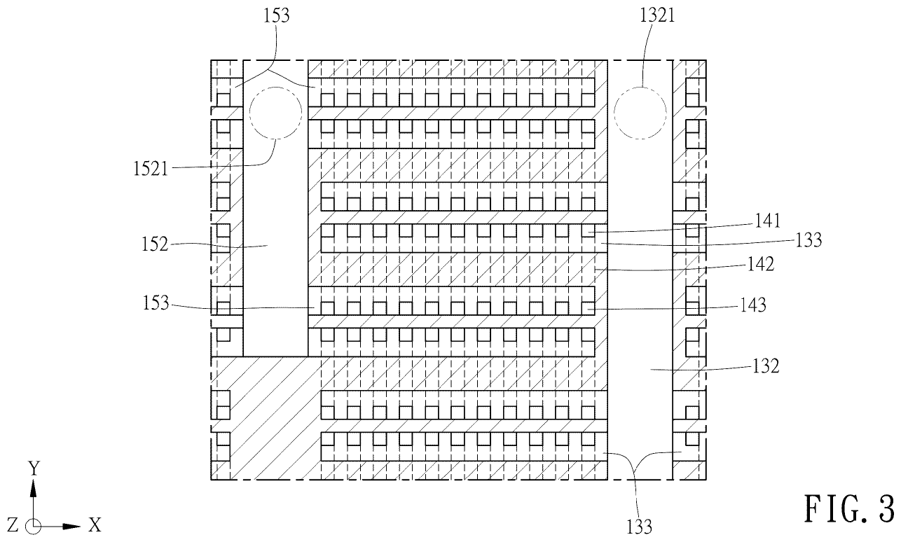

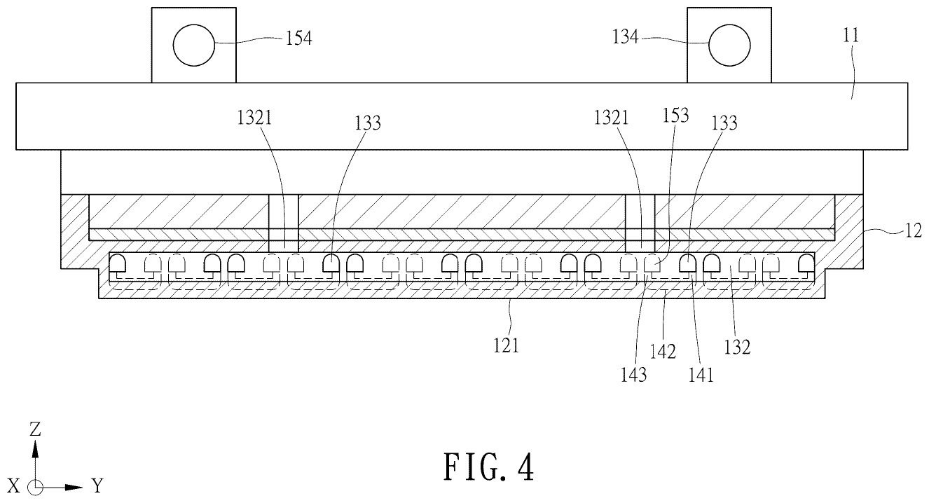

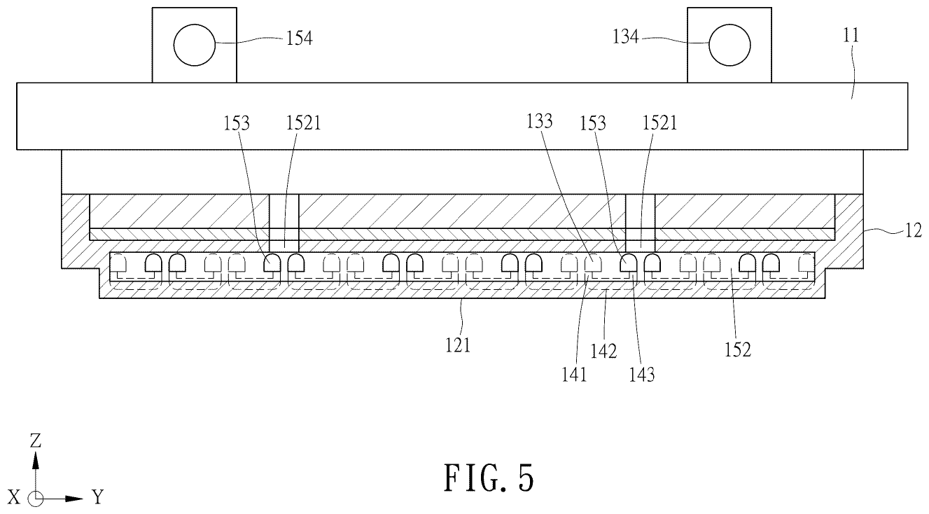

Please refer to FIG. 1 to FIG. 5 for the first embodiment of the pressing mechanism of the present invention. The pressing mechanism includes a pressing member, a providing unit, a micro channel unit, and an output unit.

The pressing member has at least one pressing face. Practically, the pressing member can be formed in a single piece or composed of a plurality of pieces. The pressing member is adapted for pressing the electronic component. The pressing member can also be a pressing-carrying member to press and move the electronic component. The pressing member can be also a carrying device to carrying the electronic component. The pressing member can be also a pre-heating device to carry and pre-heat the electronic component.

In the present embodiment, the pressing member is composed of a plurality of members. The members include a first member 11 and a second member 12. The top face of the first member 11 is defined as an install face 111 for installing on a support member, which is not shown in the drawings. The second member 12 is arranged below the first member 11. The bottom face of the second member 12 is defined as a pressing face 121 for pressing and contacting the electronic component, which is not shown in the drawings.

The providing unit has at least one main inlet channel 131, at least one branch channel 132, and at least one inlet branch channel 133 at the pressing member. The fluid at the predetermined temperature enters the branch channel 132 from the main inlet channel 131 and further enters the inlet branch channel 133 from the branch channel 132.

The branch channel 132 of the providing unit is located at the lateral side of the inlet branch channel 133. The branch channel 132 and the inlet branch channel 133 extend along different directions.

The providing unit has a plurality of rows of the inlet branch channel 133 communicating with the branch channel 132.

In the present embodiment, the providing unit has an main inlet channel 131, a plurality of branch channels 132, and a plurality of rows of the inlet branch channel 133. Specifically, the main inlet channel 131 is formed in the first member 11 and includes at least one first main inlet 1311, a plurality of main inlet sections 1312, and a plurality of second main inlets 1313 communicating with each other. The first main inlet 1311 communicates with the inlet pipe 134 and the main inlet sections 1312 so that the fluid at the predetermined temperature, such as the refrigerant at a low temperature, is injected into the main inlet section 1312 from the inlet pipe 134. The main inlet sections 1312 communicates with the second main inlets 1313 respectively to output the fluid at the predetermined temperature. The branch channels 132 are formed in the second member 12 along a Y-direction and communicate with the second main inlets 1313 via a plurality of branch inlets 1321 so as to injecting the fluid at the predetermined temperature from the main inlet channel 131 to increase the inlet flow. The rows of the inlet branch channel 133 are formed in the second member 12 along an X-direction to extend along a direction different from that of the branch channel 132. The rows of the inlet branch channel 133 communicate the branch channel 132 so that the fluid at the predetermined temperature enters the inlet branch channels 133 from the branch channel 132.

The micro channel unit has a plurality of micro channels in the pressing member near the pressing face 121. The fluid at the predetermined temperature enters the micro channels from the inlet branch channels 133 so as to exchange heat with the pressing face 121 in a larger area. Thus, the pressing face 121 is controlled at the predetermined temperature.

The micro channel of the micro channel unit has an inlet 141, at least one micro section 142, and an outlet 143 communicating with each other. The inlet 141 communicates with the inlet branch channel 133 and the at least one micro section 142 to let the fluid at the predetermined temperature enter. The outlet 143 communicates with the at least one micro section 142 and the outlet branch channel to output the heat-exchanged fluid. Besides, the inlet 141 and the outlet 143 of the micro channel have heights different from that of the micro section 142.

In the present embodiment, the micro channel unit is arranged at the second member 12 of the pressing member and has a plurality of rows of micro channel near the pressing face 121. The inlet 141 of each of the micro channels has a diameter of 0.2 mm. An end of the inlet communicates with the inlet branch channel 133, and the other end of the inlet extends along the Z-direction and communicates a micro section 142 extending along the Y-direction so that the fluid at the predetermined temperature in the inlet branch channel 133 enters the micro section 142 to allow the fluid to exchange heat with the pressing face 121. The micro section 142 extends upward along the Z-direction to communicate the outlet 143. The outlet 143 has a diameter of 0.2 mm for outputting the heat-exchanged fluid.

The providing unit has at least one main outlet channel 151, at least one converging channel 152, and at least one outlet branch channel 153. The heat-exchanged fluid enters the micro channels from the outlet branch channel 153, and further enters the converging channel 152. The heat-exchanged fluid is further output via the main outlet channel 151 from the converging channel 152.

Specifically, the converging channel 152 is located at the lateral side of the outlet branch channel 153. The converging channel 152 and the outlet branch channel 153 extends along different directions.

Specifically, the providing unit has a plurality of rows of the outlet branch channel 153 communicating with the converging channel 152.

In the present embodiment, the providing unit has a main outlet channel 151, a plurality of converging channels 152, and a plurality of rows of outlet branch channel 153. Specifically, the main outlet channel 151 is arranged in the first member 11 and has at least one first main outlet 1511, a plurality of main outlet sections 1512, and a plurality of second main outlets 1513 communicating with each other. The rows of the outlet branch channel 153 are arranged in the second member 12 along the X-direction and communicate with the converging channels 152. The outlet branch channel 153 and the converging channel 152 extend along different directions. The heat-exchanged fluid is converged into the converging channels 152 from the outlet branch channels 153. The converging channels 152 are arranged in the second member along the Y-direction and communicate with the second main outlets 1513 via the converging outlets 1521 so that the heat-exchanged fluid is output into the main outlet section 1512 from the converging channels 152. The main outlet section 1512 of the main outlet channel 151 communicates the outlet pipe 154 via the first main outlet 1511 so that the heat-exchanged fluid is output into the outlet pipe 154.

Optionally, the pressing mechanism can further include at least one heating member 16. The heating member 16 is arranged on the pressing member to increase the temperature of the pressing member. For example, the heating member 16 is arranged between the first member 11 and the second member 12, or is arranged in the second member 12, or is arranged on the pressing face 121. In the present embodiment, the heating member 16 is arranged in the second member 12.

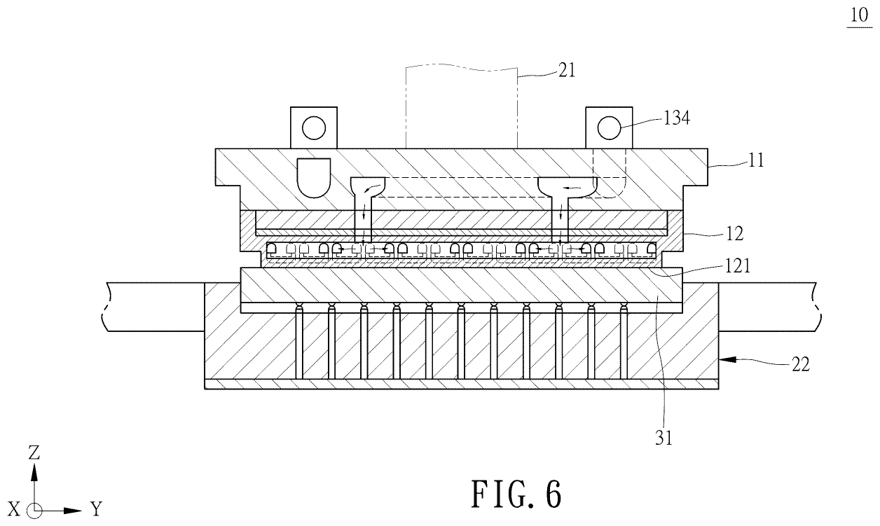

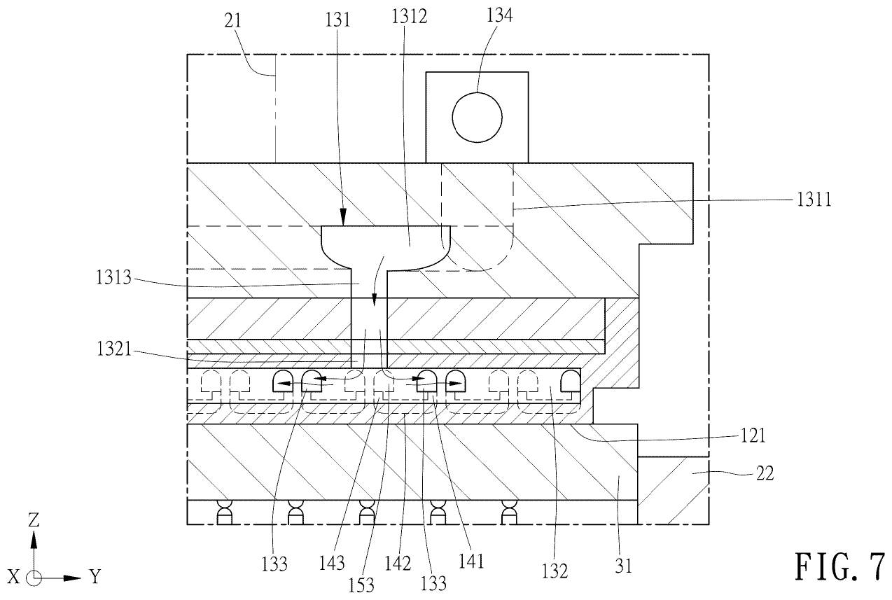

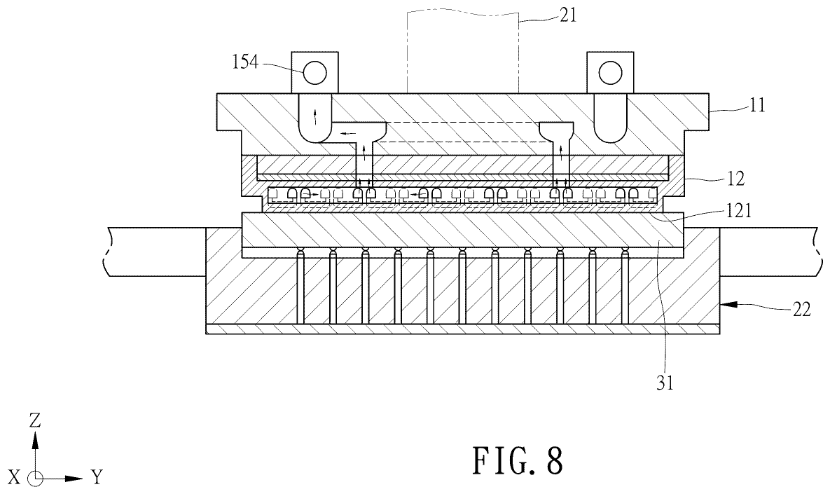

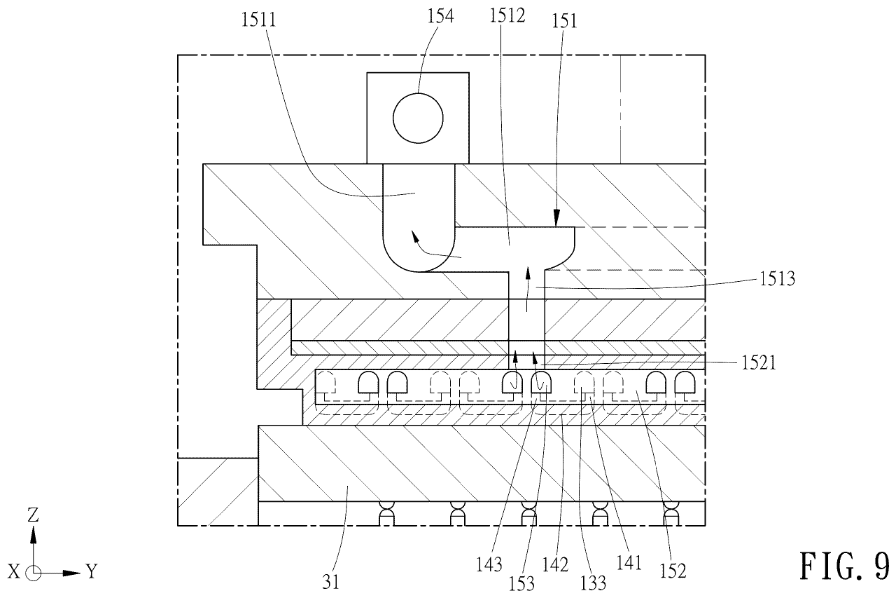

Please refer to FIG. 1, and FIG. 6 to FIG. 9, The processing device 10 of the present invention includes at least one said pressing mechanism and at least one support mechanism. The at least one pressing mechanism includes a pressing member, a providing unit, a micro channel unit, and an output unit. The at least one support mechanism has at least one support member for supporting the at least one pressing mechanism. Specifically, the support member can be fixedly arranged or movably arranged. For example, the support member can be a rack or a fixing seat to fixedly connect to the pressing mechanism. Or, the support member is a carry arm or carry seat which is movable along at least one direction to carry the pressing mechanism to move. In the present embodiment, the support member is a carry arm 21 which is driven to move along the Z-direction by a driving source, which is not shown in the drawings. The carry arm 21 is disposed on the install face 111 of the first member 11 of the pressing member. Optionally, the processing device 10 can further includes at least one testing mechanism having at least one testing member 22 to test the electronic component. In the present embodiment, the testing member 22 has a circuit board and a testing seat for receiving and testing the electronic component 31. The carry arm 21 is able to drive the first member 11, the second member 12, the providing unit, the micro channel unit, and the output unit to move toward the testing member 22 along the Z-direction so that the pressing face 121 presses the electronic component 31.

Optionally, a floating member, which is not shown in the drawings, can be arranged between the install face 111 and the support member so as to provide a cushion.

During the testing process at a low temperature, the inlet pipe 134 of the providing unit injects the refrigerant into the main inlet sections 1312 via the first main inlets 1311 of the main inlet channel 131. The refrigerant quickly flows into the branch channel 132 via the second main inlets 1313 and the branch inlet 1321 from each of the main inlet sections 1312. Because the branch channel 132 communicates with the inlet branch channels 133, the refrigerant can quickly and evenly enter the inlet branch channels 133 to keep the temperature of the refrigerant in the branch inlet channels 133 low. The inlet branch channel 133 communicates with inlets 141 of the micro channels. Each of the inlets 141 is adapted for the refrigerant to downward flow into the micro section 142. The micro sections 142 are close to the pressing face 121 and are aligned closely at the micro channels which are short. Because of the position above the pressing face 121 and the loss of temperature of channel decreasing, the refrigerant in the micro sections 142 of the micro channels can exchange heat with the pressing face 121 at the predetermined temperature. Thus, the temperature of the whole surface of the pressing face 121 is kept constant and low. As a result, the temperature of the electronic component 31 in the testing member 22 can be kept at the predetermined temperature so as to improve the performance of testing.

The heat-exchanged refrigerant in the micro sections 142 is output upward into the outlet branch channels 153 via the outlets 143. Because the converging channel 152 corresponds to the plural outlet branch channels 153, the heat-exchanged refrigerant is converged into the converging channel 152 from the outlet branch channels 153 quickly. The heat-exchanged refrigerant is further output into the second main outlet 1513 of the main channel 151 via the converging outlet 1521, and is further output into the outlet pipe 154 via the main section 1512 and the first main outlet 1511. Thus, the refrigerant can circulate quickly.

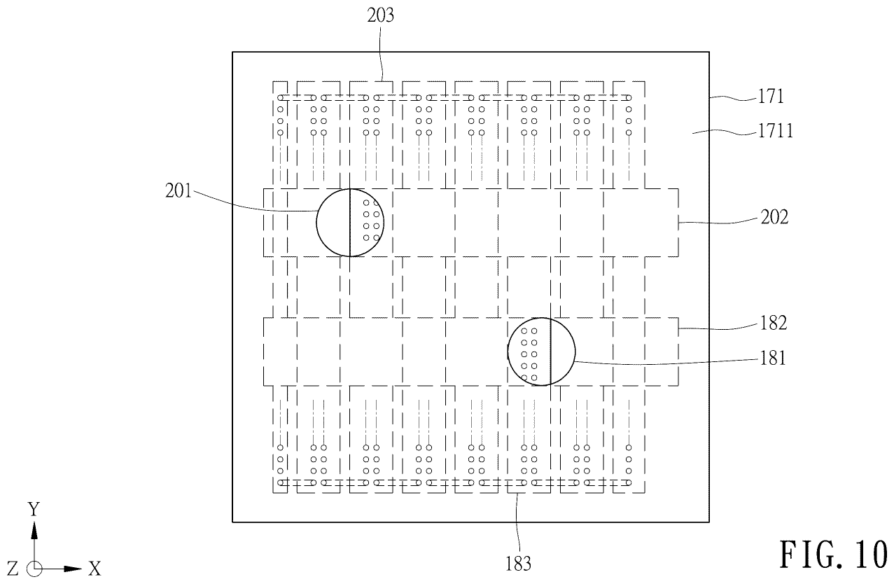

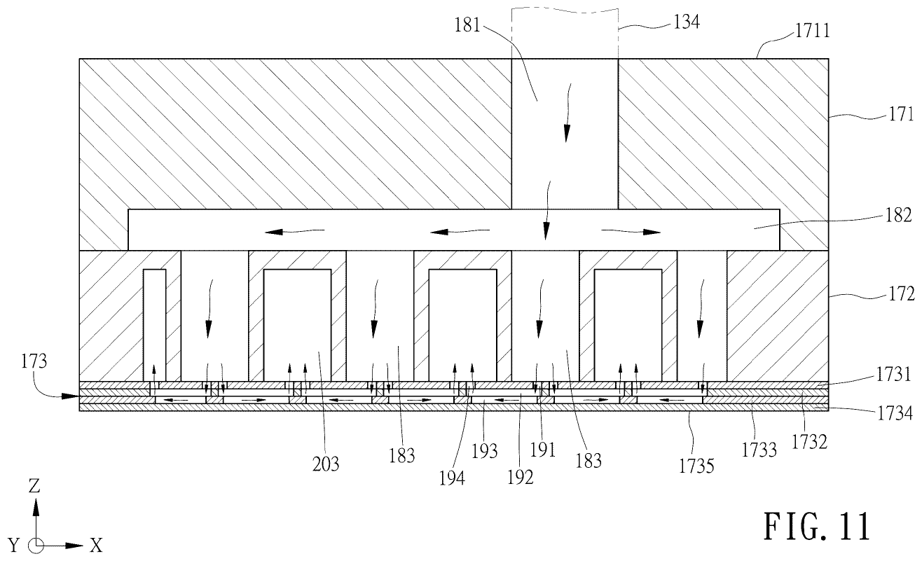

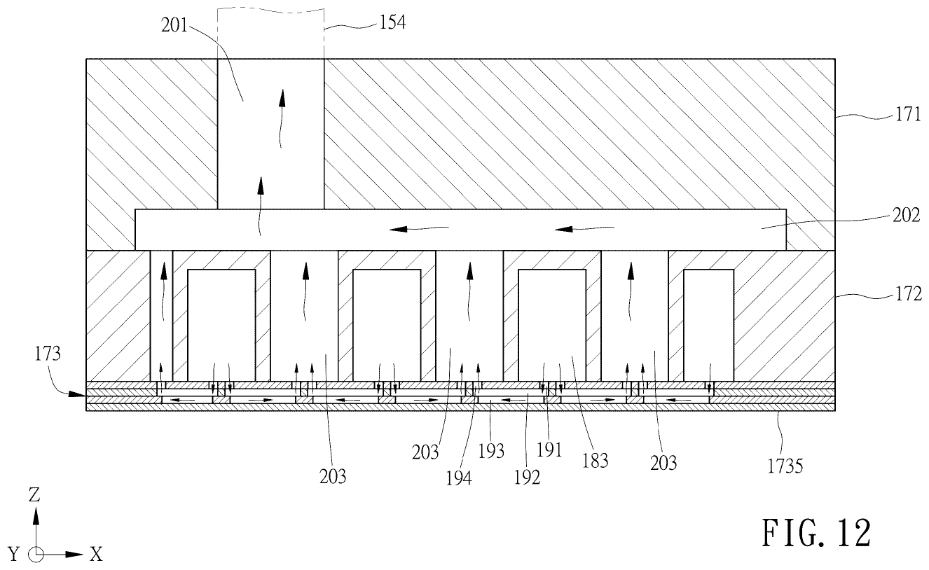

Please refer to FIG. 10 to FIG. 12 for the second embodiment of the present invention. The differences from the first embodiment includes that the pressing member is composed of a first member 171, a second member 172, and a third member 173 which are stacked together. The third member 173 includes a plurality of plates stacked together. The plates include a first plate 1731, a second plate 1732, a third plate 1733, and a fourth plate 1734. The top face of the first member 171 is defined as the install face 1711. The bottom face of the fourth plate 1734 is defined as the pressing face 1735. The providing unit has the main inlet channel 181 and a branch channel 182 communicating with each other in the first member 171. The main inlet channel 181 communicates with the inlet pipe 134 and the branch channel 182 so as to inject the fluid at the predetermined temperature from the inlet pipe 134 into the branch channel 182. The providing unit has a plurality of inlet branch channels 183 in the second member 172. The inlet branch channels 183 communicate with the branch channel 182 and are located below the branch channel 182. The fluid at the predetermined temperature is evenly distributed into the inlet branch channels 183 from the branch channel 182. The micro channel unit has a plurality of micro channels in the third member 173. Specifically, the micro channels are enclosed by the plates of the third member 173. In the present embodiment, each of the micro channels has an inlet 191 communicating the inlet branch channel 183 at the first plate 1731 of the third member 173, and has a first micro section 192 and a second micro section 193 communicating with the inlet 191 and extending along the X-direction at the second plate 1732 and the third plate 1733. The fluid in the first micro section 192 and the second micro section 193 exchanges heat with the pressing face 1735 to control the temperature of the electronic component. The micro channel has an outlet 194 communicating with the first micro section 192 at the first plate 1731 to output the heat-exchanged fluid. The output unit has a main outlet channel 201 and a converging channel 202 at the first member 171 of the pressing member. The main outlet channel 201 communicates with the outlet pipe 154 and the converging channel 202. The outlet unit further has a plurality of outlet branch channels 203. The outlet branch channels 203 do not communicate with the inlet branch channels 183, and the outlet branch channels 203 and the inlet branch channels 183 are arranged staggered. The outlet branch channels 203 are located below the converging channel 202 and communicate with the outlets 194 of the micro channels so that the heat-exchanged fluid is injected into the outlet branch channels 203 from the outlets 194. The heat-exchanged fluid is further injected into the converging channel 202 from the outlet branch channels 203, and is output to the outlet pipe 154 from the main outlet channel 201.

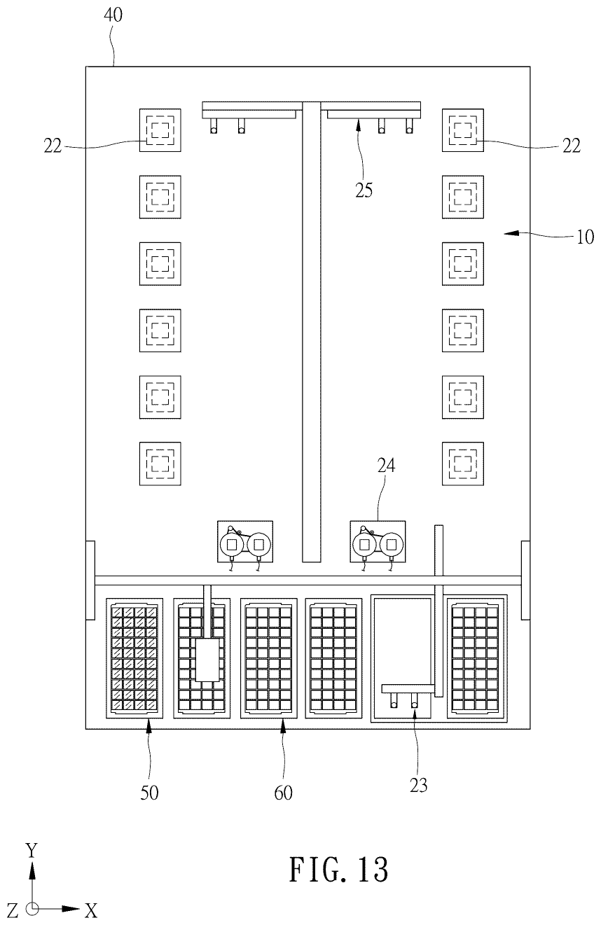

Please refer to FIG. 1 to FIG. 9 and FIG. 13. The processing device 10 is used in a processing machine of electronic component. The processing machine includes a machine 40, a providing device 50, a collecting device 60, a processing device 10, and a central control device, which is not shown in the drawings. The providing device 50 is disposed on the machine 40 and has at least one providing member to receive at least one electronic component to be tested. The collecting device 60 is disposed on the machine 40 and has at least one collecting member to receive at least one tested electronic component. The processing device 10 is disposed on the machine 40 and includes at least one pressing mechanism and at least one support mechanism, and further includes at least one testing mechanism and at least one carrying mechanism. The testing mechanism has at least one testing member 22 to test the electronic component. The carrying mechanism has at least one carrying member to carry and move the electronic component. In the present embodiment, the carrying mechanism has a first carrying member 23 to pick up the electronic component to be tested from the providing member of the providing device 50 and to move it to a second carrying member 24. A third carrying member 25 picks up the electronic component to be tested from the second carrying member 24 to move it to the testing member for test process. The pressing member presses the electronic component and controls the temperature of the electronic component. The third carrying member 25 further moves the tested electronic component to the second carrying member 24. The first carrying member 23 picks up the tested electronic component from the second carrying member 24 and classify and collect it at the collecting device 60 according to the result of test. The central control device, which is not shown in the drawings, is adapted for controlling and integrating the operations of the devices mentioned above to achieve automatic process.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A pressing mechanism, including:
a pressing member, having at least one pressing face;
a providing unit, having at least one main inlet channel, at least one branch channel, and at least one inlet branch channel at the pressing member, the main inlet channel being adapted for injecting a fluid at a predetermined temperature into the branch channel, the branch channel being adapted for injecting the fluid at the predetermined temperature into the inlet branch channel;
a micro channel unit, having a plurality of micro channels at the pressing member near the pressing face, the micro channels being adapted for injecting the fluid at the predetermined temperature into the inlet branch channel and for exchanging heat with the pressing face to keep a temperature of the pressing face constant;
an outlet unit, having at least one main outlet channel, at least one converging channel, and at least one outlet branch channel at the pressing member, the outlet branch channel being adapted for injecting an heat-exchanged fluid into the micro channels and for converging the heat-exchanged fluid into the converging channel, the converging channel being adapted for injecting the heat-exchanged fluid into the main outlet channel to output the heat-exchanged fluid.

2. The pressing mechanism of claim 1, wherein each of the micro channels has an inlet, at least one micro section, and an outlet, the inlet communicates with the branch channel and the at least one micro section for the fluid at the predetermined temperature to enter therein, the outlet communicates the at least one micro section and the outlet branch channel to make the heat-exchanged fluid leave.

3. The pressing mechanism of claim 2, wherein a height of each of the inlet and the outlet of the micro channel is different from a height of the micro section.

4. The pressing mechanism of claim 1, wherein the branch channel of the providing unit is located at a lateral side of the inlet branch channel, the branch channel and the inlet branch channel extend along different directions.

5. The pressing mechanism of claim 1, wherein the providing unit has a plurality of rows of the inlet branch channel, the rows of the inlet branch channel communicate with the branch channel.

6. The pressing mechanism of claim 1, wherein the converging channel of the outlet unit is located at a lateral side of the branch channel, the converging channel and the branch channel extend along different directions.

7. The pressing mechanism of claim 1, wherein the outlet unit has a plurality of rows of the outlet branch channel, the rows of the outlet branch channel communicate with the converging channel.

8. The pressing mechanism of claim 1, wherein the pressing member includes a first member and a second member, the second member has the pressing face, the providing unit has the main inlet channel in the first member and has the branch channels and the rows of the inlet branch channel in the second member.

9. The pressing mechanism of claim 8, wherein the main inlet channel has at least one first main inlet, a plurality of main inlet sections, and a plurality of second main inlets at the first member communicating with each other, the second main inlets are adapted for injecting the fluid at the predetermined temperature into the branch channels.

10. The pressing mechanism of claim 8, wherein the outlet unit has the main channel in the first member and has the converging channel and the outlet branch channels in the second member.

11. The pressing mechanism of claim 10, wherein the main outlet channel has at least one first main outlet, a plurality of main outlet sections, and a plurality of second main outlets at the first member communicating with each other, the converging channel is adapted for outputting the heat-exchanged fluid via the second main outlets.

12. The pressing mechanism of claim 1, wherein the pressing member includes a first member, a second member, and a third member, the providing unit has the main channel and the branch channel in the first member communicating with each other and has a plurality of inlet branch channels in the second member, the inlet branch channel communicates with the branch channel and is located below the branch channel, the micro channel unit has a plurality of the micro channels in the third member.

13. The pressing mechanism of claim 12, wherein the outlet unit has the main outlet channel and the converging channel at the first member communicating with each other and has a plurality of the outlet branch channels at the second member, the outlet branch channels communicate with the converging channel and are located below the converging channel.

14. The pressing mechanism of claim 12, wherein the third member is composed of a plurality of plates, the plates are stacked together to enclose the micro channels.

15. The pressing mechanism of claim 1, further including a heating member, the heating member is arranged at the pressing member.

16. A processing device, including:
at least one the pressing mechanism of claim 1;
at least one support structure, having at least one support member to support the at least one pressing mechanism.

17. A processing machine, including:
a machine;
a providing device, arranged at the machine, having at least one providing member for receiving at least one electronic component to test;
a collecting device, arranged at the machine, having at least one collecting member for receiving at least one tested electronic component;
at least one the processing device of claim 16, arranged at the machine, including at least one said pressing mechanism and at least one said support structure, and further including at least one testing mechanism and at least one carrying mechanism, the at least one testing mechanism having at least one testing member for testing the electronic component, the at least one carrying mechanism having at least one carrying member for carrying and moving the electronic component;
a central control device, for controlling and integrating the devices and the mechanisms to achieve automatic process.
